(19) United States
(12) Patent Application Publication
(10) Pub. No.: US 2010/0209595 A1
(43) Pub. Date: Aug. 19, 2010

(54) Methods of Forming Strontium Ruthenate Thin Films and Methods of Manufacturing Capacitors Including the Same

(76) Inventors: Oh-Seong Kwon, Hwaseong-si (KR); Kyu-Ho Cho, Hwaseong-si (KR); Jung-Hee Chung, Suwon-si (KR); Jin-Yong Kim, Guri-si (KR); Wan-Don Kim, Yongin-si (KR); Youn-Soo Kim, Yongin-si (KR); Yong-Suk Tak, Seoul (KR)

Correspondence Address: MYERS BIGEL SIBLEY & SAJOVEC, PO BOX 37428, RALEIGH, NC, 27627, US

(21) Appl. No.: 12/708,704

(22) Filed: Feb. 19, 2010

(30) Foreign Application Priority Data
Feb. 19, 2009 (KR) 10-2009-0013907

(51) Int. Cl. B05D 5/12; C23C 16/00

(52) U.S. Cl. 427/79; 427/248.1

(57) ABSTRACT

In a method of forming a strontium ruthenate thin film using water vapor as an oxidizing agent, a strontium source and a ruthenium source are used. The strontium source includes a cyclopentadienyl (Cp) ligand, an alkoxide ligand, an alkyl ligand, an amide ligand or a halide ligand, and the ruthenium source includes a beta diketonate ligand.

### RELATED APPLICATION DATA

This application claims priority under 35 USC §119 to Korean Patent Application No. 10-2009-0013907, filed on Feb. 19, 2009 in the Korean Intellectual Property Office (KIPO), the contents of which are incorporated herein by reference in its entirety.

### FIELD OF THE INVENTION

Exemplary embodiments relate to methods of forming strontium ruthenate thin films and methods of manufacturing capacitors including the same.

### BACKGROUND

As semiconductor devices have become highly integrated, methods of increasing capacitance of capacitors have been developed. For example, a lower electrode of a capacitor may have an enlarged effective area by adopting a cylindrical structure or a pin structure. Alternatively, a dielectric layer of the capacitor may include a metal oxide having a high dielectric constant such as strontium ruthenate (SrRuO₃), barium strontium titanate (BST), etc.

Meanwhile, conductive metal oxide thin films have been used for the lower electrode. Particularly, a strontium ruthenate thin film may have desirable characteristics as the lower electrode. The strontium ruthenate thin film may be formed by a chemical vapor deposition (CVD) process or an atomic layer deposition (ALD) process. When the strontium ruthenate thin film is formed by an ALD process, a strontium source and a ruthenium source may be reacted with an oxidizing agent, and a substitution reaction between the ligands of the sources and the oxidizing agent may occur. However, there are generally limitations associated with the type of sources and the oxidizing agent, particularly when the sources include a volatile material such as ruthenium.

For example, when beta diketonate complexes are used for the ruthenium source in the ALD process, oxygen or water vapor may not be used for the oxidizing agent because a substitution reaction between the ruthenium source and the oxidizing agent may not occur. In this case, ozone may be used as the oxidizing agent, however, forming a stoichiometric strontium ruthenate may be more difficult.

### SUMMARY

Example embodiments provide methods of forming strontium ruthenate thin films having desirable characteristics.

Example embodiments provide methods of manufacturing capacitors using methods of forming strontium ruthenate thin films having desirable characteristics.

According to example embodiments, there is provided a method of forming a strontium ruthenate thin film using water vapor as an oxidizing agent in an atomic layer deposition (ALD) process. In the ALD process, a strontium source and a ruthenium source are used. The strontium source includes a cyclopentadienyl (Cp) ligand, an alkoxide ligand, an alkyl ligand, an amide ligand or a halide ligand, and the ruthenium source gas includes a beta diketonate ligand.

In example embodiments, the ruthenium source may further include a tetramethylheptanedionate (TMHD) ligand and/or a methoxytetramethylheptanedionate (METHD) ligand.

In example embodiments, the strontium source may include strontium n-propyl cyclopentadienyl, strontium iso-propyl cyclopentadienyl, strontium n-butoxide, strontium diketiminate, strontium dikeminine or strontium chloride.

In example embodiments, when the strontium ruthenate thin film is formed, i) a first ALD process may be performed using water vapor and the strontium source including a ligand having good reactivity with water vapor, ii) a second ALD process may be performed using water vapor and the ruthenium source including the beta diketonate ligand, and steps i) and ii) may be performed at least twice.

According to example embodiments, there is provided a method of forming a strontium ruthenate thin film. In the method, i) a strontium source is provided onto a substrate to be chemically adsorbed on the substrate. The strontium source includes a cyclopentadienyl (Cp) ligand, an alkoxide ligand, an alkyl ligand, an amide ligand or a halide ligand; ii) a remaining portion of the strontium source that is not chemically adsorbed on the substrate is removed by a first purge process; iii) water vapor is provided onto the substrate to form a strontium oxide thin film on the substrate. The strontium source is reacted with the water vapor; iv) a ruthenium source is provided onto the strontium oxide thin film to be chemically adsorbed on the strontium oxide thin film. The ruthenium source includes a beta diketonate ligand; v) a remaining portion of the ruthenium source that is not chemically adsorbed on the strontium oxide thin film is removed by a second purge process; and vi) water vapor is provided onto the strontium oxide thin film to form a ruthenium oxide thin film. The ruthenium source is reacted with the water vapor.

In example embodiments, a third purge process may be performed after forming the strontium oxide thin film and a fourth purge process may be performed after forming the ruthenium oxide thin film.

In example embodiments, steps i) through vi) may be performed at least twice.

According to example embodiments, there is provided a method of manufacturing a capacitor. In the method, a lower electrode is formed using a strontium ruthenate thin film. A dielectric layer is formed on the lower electrode. An upper electrode is formed on the dielectric layer. The strontium ruthenate thin film is formed using water vapor, a strontium source and a ruthenium source by an ALD process. The strontium source includes a cyclopentadienyl (Cp) ligand, an alkoxide ligand, an alkyl ligand, an amide ligand or a halide ligand, and the ruthenium source gas includes a beta diketonate ligand.

According to some example embodiments, when a strontium ruthenate thin film is formed, a strontium source including a ligand having good reactivity with water vapor is used so that a reaction site to which a ruthenium source having a beta diketonate ligand may be adsorbed. Thus, water vapor may be used again as an oxidizing agent for the ruthenium source. The strontium ruthenate thin film may have a large amount of ruthenium content, and thus, a capacitor having the strontium ruthenate thin film serving as a lower electrode may have desirable characteristics.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is a flowchart illustrating a method of forming a strontium ruthenate thin film by an atomic layer deposition (ALD) process in accordance with example embodiments;

FIGS. 2 to 7 are cross-sectional views illustrating a method of manufacturing a capacitor of a transistor using the method of forming the strontium ruthenate thin film in accordance with example embodiments;

FIG. 8 is a graph illustrating ruthenium contents in a strontium ruthenate thin film when different oxidizing agents are used in an ALD process; and

FIG. 9 is a graph illustrating step coverage characteristics of a strontium ruthenate thin film when the strontium ruthenate thin film was formed on a cylindrical structure having an aspect ratio of about 13:1 using water vapor as an oxidizing agent in an ALD process.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

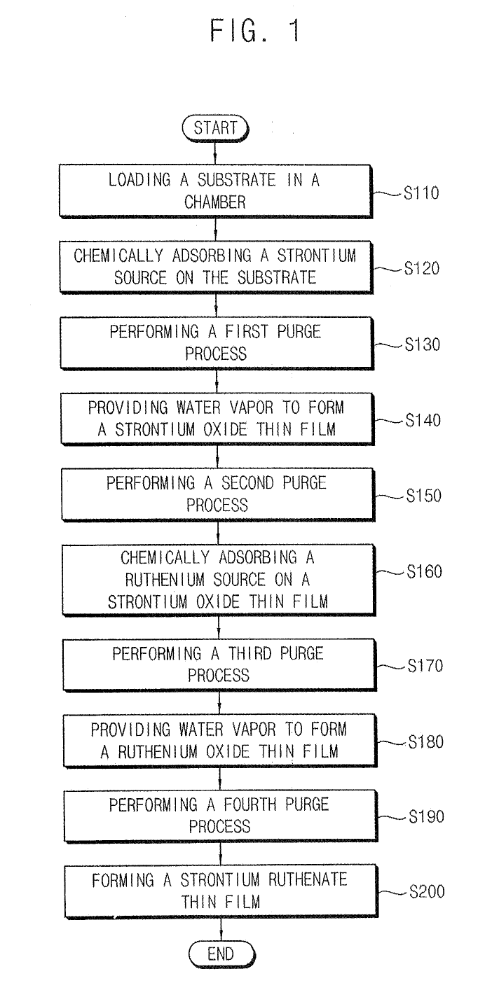

FIG. 1 is a flowchart illustrating a method of forming a strontium ruthenate thin film by an atomic layer deposition (ALD) process in accordance with example embodiments.

Referring to FIG. 1, in step S110, a substrate (not shown) may be provided in a chamber (not shown). The substrate may be loaded onto a stage (not shown) in the chamber, and an internal pressure and/or temperature of the chamber may be controlled.

The substrate may include a semiconductor substrate or an assembly of substrates. The semiconductor substrate may include a doped polysilicon substrate or a single crystalline silicon substrate. In example embodiments, the semiconductor substrate may include a silicon oxide layer or a metal layer thereon. The assembly of substrates may include multi-layers of a metal layer, a metal oxide layer and/or a metal nitride layer. For example, the metal layer may include platinum, iridium, rhodium, ruthenium, aluminum or gallium. The metal oxide layer may include iridium oxide, ruthenium oxide or silicon oxide. The metal nitride layer may include titanium nitride, tantalum nitride or silicon metal nitride.

In step S120, a strontium source may be provided onto the substrate to be chemically adsorbed thereon. The strontium source may include a ligand that reacts well with water vapor (H₂O). For example, the strontium source may include a cyclopentadienyl (Cp) ligand, an alkoxide ligand, an alkyl ligand, an amide ligand or a halide ligand together with strontium as a central metal.

Particularly, the strontium source may include strontium n-propyl cyclopentadienyl, strontium iso-propyl cyclopentadienyl, strontium n-butoxide, strontium diketiminate, strontium dikeminine, strontium chloride, etc.

The strontium source may be provided into the chamber by a precursor providing apparatus such as a bubbling system, an injection system or a liquid delivery system (LDS). When the strontium source is provided by the bubbling system, a liquid strontium source may be bubbled by a carrier gas to be vaporized, and the vaporized strontium source gas may be introduced into the chamber by the carrier gas.

The carrier gas may include an inert gas such as argon, helium, nitrogen, neon, etc. These may be used alone or in combination thereof. In example embodiments, hydrogen gas may be provided into the chamber together with the carrier gas. A flow rate of the carrier gas may be controlled in consideration of process factors such as a deposition rate of the thin film, a vapor pressure of the strontium source, temperature, etc. In an example embodiment, the strontium source may be provided for about 0.1 to about 3 seconds. A first portion of the strontium source may be chemically adsorbed onto the substrate and a second portion thereof may be physically adsorbed onto the substrate or drift into the chamber. Ligands or central metals of the strontium source may be chemically reacted with the substrate, so that the chemical adsorption may occur.

In step S130, the second portion of the strontium source may be removed by a first purge process. In the first purge process, a first purge gas may be provided into the chamber. For example, the first purge gas may include nitrogen, argon, helium and/or hydrogen. These gases may be used alone or in combination thereof. In example embodiments, the first purge gas may be provided for about 0.1 to about 5 seconds.

In step S140, an oxidizing agent may be provided onto the substrate to form a strontium oxide thin film on the substrate. In example embodiments, water vapor (H₂O) may be provided as the oxidizing agent. The water vapor provided into the chamber may be reacted with the ligands of the strontium source so that the strontium oxide thin film having a reaction site to which a ruthenium source having a beta diketonate ligand may be chemically adsorbed in a subsequent process. For example, the reaction site may include a hydroxyl radical.

In step S150, a remaining portion of the oxidizing agent that is not reacted with the ligands of the strontium source may be removed by a second purge process. For example, the second purge gas may include nitrogen, argon, helium and/or hydrogen. These gases may be used alone or in combination thereof. In example embodiments, the second purge gas may be provided for about 0.1 to about 5 seconds.

In step S160, a ruthenium source having a beta diketonate ligand may be provided onto the substrate to be chemically adsorbed on the strontium oxide thin film. The beta diketonate ligand may not be reacted with water vapor. For example, the ruthenium source may include the beta diketonate ligand together with a derivative thereof, e.g., a tetramethylheptanedionate (TMHD) ligand and/or a methoxytetramethylheptanedionate (METHD) ligand.

The ruthenium source may be provided into the chamber by a precursor providing apparatus such as a bubbling system, an injection system or a LDS. When the ruthenium source is provided by the bubbling system, a liquid ruthenium source may be bubbled by a carrier gas to be vaporized, and the vaporized ruthenium source gas may be introduced into the chamber by the carrier gas.

The carrier gas may include an inactive gas such as argon, helium, nitrogen, neon, etc. These gases may be used alone or in combination thereof. In example embodiments, hydrogen gas may be provided into the chamber together with the carrier gas. A flow rate of the carrier gas may be controlled in consideration of process factors such as a deposition rate of the thin film, a vapor pressure of the ruthenium source, temperature, etc. In an example embodiment, the ruthenium source may be provided for about 0.1 to about 3 seconds. A first portion of the ruthenium source may be reacted with the reaction site of the strontium oxide thin film to be chemically adsorbed onto the strontium oxide thin film, and a second portion thereof may be physically adsorbed onto the strontium oxide thin film or drift into the chamber. Ligands or central metals of the ruthenium source may be chemically reacted with the reaction site of the strontium oxide thin film so that the chemical adsorption may occur. The first portion of the ruthenium source that is chemically adsorbed onto the strontium oxide thin film may be reacted with water vapor serving as an oxidizing agent in a subsequent process at least because the bonding force between the beta diketonate ligand and ruthenium may be weakened.

In step S170, the second portion of the ruthenium source may be removed by a third purge process. In the third purge process, a third purge gas may be provided into the chamber. For example, the third purge gas may include nitrogen, argon, helium and/or hydrogen. These gases may be used alone or in combination thereof. In example embodiments, the third purge gas may be provided for about 0.1 to about 5 seconds.

In step S180, an oxidizing agent may be provided into the chamber to form a ruthenium oxide thin film on the strontium oxide thin film. In example embodiments, water vapor (H₂O) may be provided as the oxidizing agent. The water vapor provided into the chamber may be reacted with the beta diketonate ligand of the ruthenium source, which has a weakened binding force with ruthenium so that the ruthenium oxide thin film may be formed. In example embodiments, an inactive water vapor may be used as the oxidizing agent.

In step S190, a remaining portion of the oxidizing agent that is not reacted with the ligands of the ruthenium source may be removed by a fourth purge process. For example, the fourth purge gas may include nitrogen, argon, helium and/or hydrogen. These may be used alone or in combination thereof. In example embodiments, the fourth purge gas may be provided for about 0.1 to about 5 seconds.

In step S200, the steps S120 to S190 may be repeatedly performed, e.g., at least twice, thereby forming the strontium ruthenate thin film on the substrate.

Particularly, the strontium oxide thin film and the ruthenium oxide thin film may be formed alternately on the substrate to have a relatively thin thickness so that the strontium in the strontium oxide thin film may move to the ruthenium oxide thin film, and vice versa. Thus, the single strontium ruthenate thin film may be formed.

The concentration of ruthenium atoms in the strontium ruthenate thin film may be controlled, and thus a stoichiometric strontium ruthenate thin film may be formed.

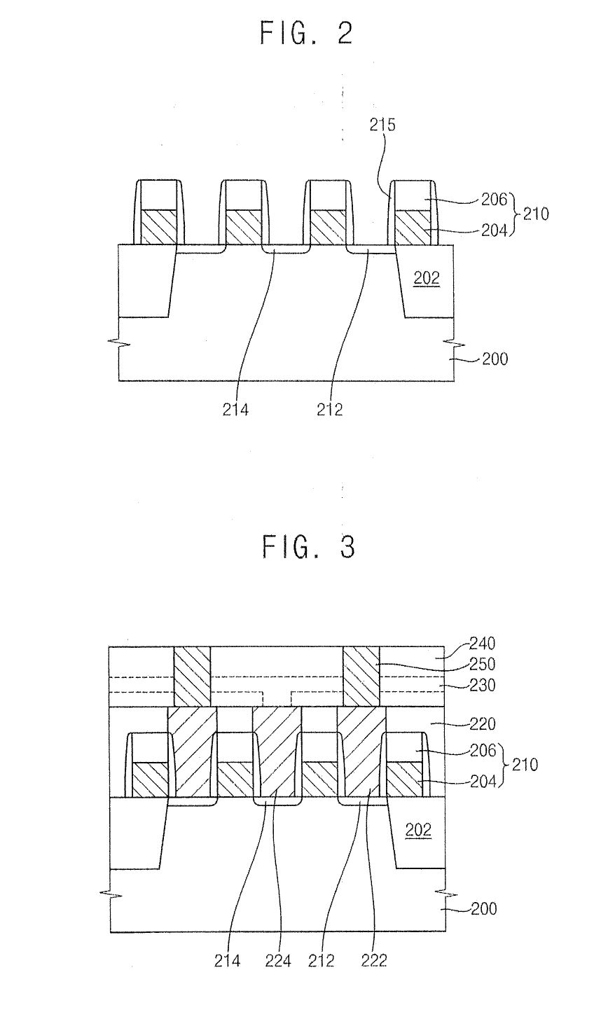

FIGS. 2 to 7 are cross-sectional views illustrating a method of manufacturing a capacitor of a transistor using a method of forming the strontium ruthenate thin film in accordance with example embodiments.

Referring to FIG. 2, an isolation layer 202 may be formed on a substrate 200. The isolation layer 202 may be formed by a shallow trench isolation (STI) process. The substrate 200 may be divided into an active region and a field region by the isolation layer 202. A gate insulation layer (not shown) may be formed on the substrate 200. The gate insulation layer may be formed by a thermal oxidation process, a CVD process or an ALD process. The gate insulation layer may be formed using silicon oxide or a high-dielectric (k) material.

A first conductive layer and a gate mask 206 may be sequentially formed on the substrate. The first conductive layer may be formed using doped polysilicon and/or a metal. The gate mask 206 may be formed using, e.g., silicon nitride.

The first conductive layer and the gate insulation layer may be patterned using the gate mask as an etching mask to form a gate electrode 204 and a gate insulation layer pattern (not shown), respectively. The gate mask 206 and the gate electrode 204 may define a gate structure 210.

A spacer layer may be formed on the substrate 200 to cover the gate structure 210. The spacer layer may be formed using, e.g., silicon nitride. The spacer layer may be etched by an anisotropic etching process to form a gate spacer 215 on a sidewall of the gate structure 210. Impurities may be implanted into the substrate 200 by an ion implantation process using the gate structure 210 and the gate spacer 215 as an ion implantation mask. A heat treatment process may be further performed on the substrate 200. Thus, a first impurity region 212 and a second impurity region 214 may be formed at upper portions of the substrate 200 adjacent to the gate structure 210. The first and second impurity regions 212 and 214 may serve as source/drain regions of the transistor. As a result, the transistor including the gate structure 210 and the source/drain regions 212 and 214 may be manufactured.

Referring to FIG. 3, a first insulating interlayer 220 may be formed on the substrate 200 to cover the transistor. The first insulating interlayer 220 may be formed using borophosphorsilicate glass (BPSG), phosphorsilicate glass (PSG), spin on glass (SOG), plasma-enhanced tetraethylorthosilicate (PE-TEOS), undoped silicate glass (USG) or high density plasma chemical vapor deposition (HDP-CVD) oxide. The first insulating interlayer 220 may be formed by a CVD process, a plasma-enhanced chemical vapor deposition (PE-CVD) process, an HDP-CVD process, etc.

An upper portion of the first insulating interlayer 220 may be planarized by a chemical mechanical polishing (CMP) process and/or an etch back process. In example embodiments, the first insulating interlayer 220 may have a height higher than that of the gate structure 210.

The first insulating interlayer 220 may be partially removed to form first and second holes (not shown) through the first insulating interlayer 220. The first hole may expose the first impurity region 212 and the second hole may expose the second impurity region 214.

A second conductive layer may be formed on the substrate 200 and the first insulating interlayer 220 to fill the first and second holes. The second conductive layer may be formed using doped polysilicon, a metal or a metal nitride.

An upper portion of the second conductive layer may be planarized until a top surface of the first insulating interlayer is exposed. Thus, a first plug 222 and a second plug 224 may be formed in the first and second holes, respectively. The first and second plugs 222 and 224 may contact the first and second impurity regions 212 and 214, respectively.

A second insulating interlayer (not shown) may be formed on the first insulating interlayer 220 and the first and second plugs 222 and 224. The second insulating interlayer may be partially removed form a third hole (not shown) through the second insulating interlayer. The third hole may expose the second plug 224.

A third conductive layer (not shown) may be formed on the first insulating interlayer 220 and the second insulating interlayer to fill the third hole. The third conductive layer may be formed using doped polysilicon, a metal or a metal nitride. In example embodiments, the third conductive layer may be formed to have a multi-layered structure of a metal layer and a metal nitride layer. For example, the third conductive layer may be formed to have a tungsten layer and a titanium/titanium nitride layer. The third conductive layer may be patterned to form a bit line 230 on the second insulating interlayer and the second plug 224. The bit line 230 may be electrically connected to the second impurity region 214 via the second plug 224.

A third insulating interlayer 240 may be formed on the second insulating interlayer to cover the bit line 230. The third insulating interlayer 230 may be formed using BPSG, PSG, SOG, PE-TEOS, USG or HDP-CVD oxide.

The third insulating interlayer 240 and the second insulating interlayer may be partially removed to form a fourth hole (not shown) through the third insulating interlayer 240 and the second insulating interlayer. The fourth hole may expose the first plug 222.

A fourth conductive layer (not shown) may be formed on the third insulating interlayer 240 and the first plug 222 to fill the fourth hole. The fourth conductive layer may be formed using doped polysilicon, a metal or a metal nitride. An upper portion of the fourth conductive layer may be planarized to form a third plug 250 in the fourth hole. The third plug 250 may be electrically connected to the first impurity region 212 via the first plug 222.

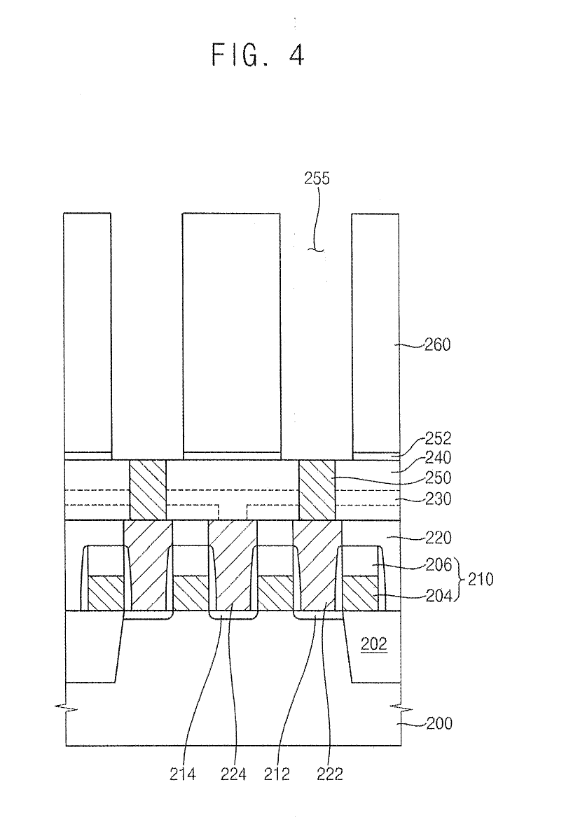

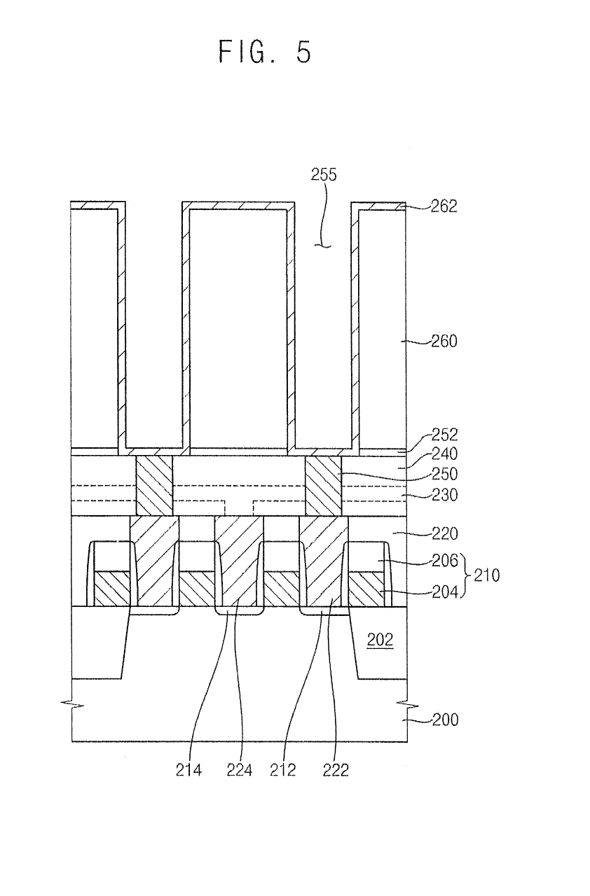

Referring to FIG. 4, an etch stop layer 252 may be formed on the third insulating interlayer 240 and the third plug 250. The etch stop layer 252 may be formed using a nitride or a metal oxide. In example embodiments, the etch stop layer 252 may be formed to have a thickness of about 10 to about 200 Å.

A mold layer 260 may be formed on the etch stop layer 252. The mold layer 260 may be formed using a silicon oxide. For example, the mold layer 260 may be formed using BPSG, PSG, SOG, PE-TEOS, USG or HDP-CVD oxide. In example embodiments, the mold layer 260 may be formed to have a multi-layered structure in which layers may have different etch rates.

The mold layer 260 and the etch stop layer 252 may be partially removed by an etching process to form an opening 255 exposing the third plug 250.

Referring to FIG. 5, a lower electrode layer 262 may be formed on a bottom and a sidewall of the opening 255 and the mold layer 260 to contact the third plug 250. In example embodiments, a strontium ruthenate thin film may be formed as the lower electrode layer 262.

The strontium ruthenate thin film may be formed by processes substantially the same as those illustrated with reference to FIG. 1, and thus detailed explanations are omitted here.

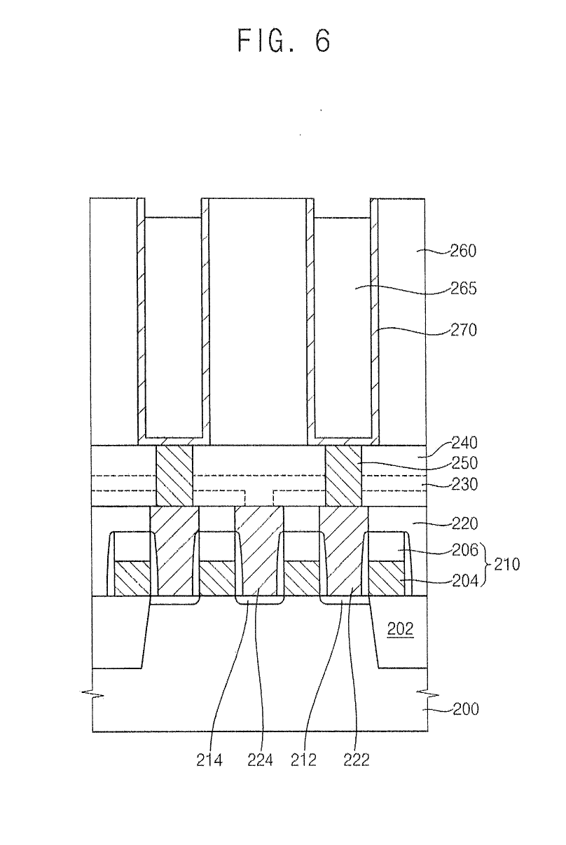

Referring to FIG. 6, a buffer layer may be formed on the lower electrode layer 262 to fill the opening 255. The buffer layer may be formed using an oxide such as a silicon oxide. An upper portion of the buffer layer may be removed until a portion of the lower electrode layer 262 on the mold layer 260 is exposed, thereby forming a buffer layer pattern 265 in the opening 255. When the buffer layer includes SOG, the removal process may be performed using an etching solution including hydrogen fluoride.

The portion of the lower electrode layer 262 on the mold layer may be removed by a dry etching process, thereby forming a lower electrode 270 on the bottom and sidewall of the opening 255. The lower electrode 270 may have a cylindrical shape.

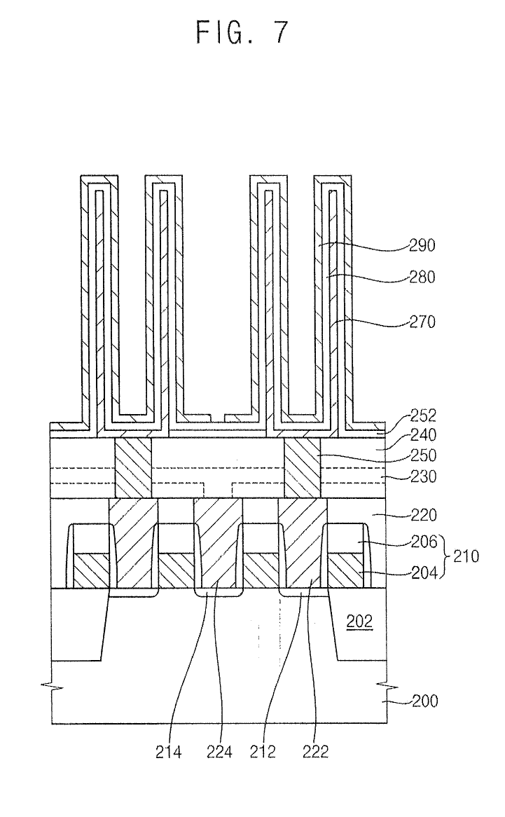

Referring to FIG. 7, the buffer layer pattern 265 and the mold layer 260 may be removed by a wet etching process. In example embodiments, the wet etching process may be performed using limulus amoebocyte lysate (LAL) solution including deionized water, ammonium fluoride and hydrogen fluoride.

A dielectric layer 280 may be formed on the lower electrode 270. The dielectric layer 280 may be formed using a metal oxide having a high dielectric constant. For example, the dielectric layer 280 may be formed using aluminum oxide or hafnium oxide.

An upper electrode 290 may be formed on the dielectric layer 280. The upper electrode 290 may be formed using doped polysilicon, a metal and/or a metal nitride. In example embodiments, the upper electrode 290 may be formed using titanium and/or titanium nitride. The upper electrode 290 may be formed by a CVD process or a physical vapor deposition (PVD) process such as a sputtering process. Thus, the capacitor may be formed.

Evaluation of Ruthenium Content in a Strontium Ruthenate Thin Film

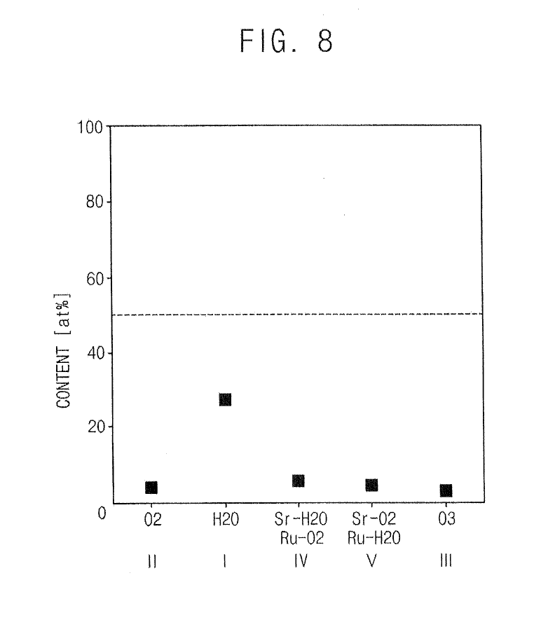

FIG. 8 is a graph illustrating ruthenium contents in a strontium ruthenate thin film when different oxidizing agents are used in an ALD process. In FIG. 8, results of one Example and 4 Comparative Examples are illustrated.

Particularly, I indicates a ruthenium content in a strontium ruthenate thin film when water vapor was used as an oxidizing agent in an ALD process in accordance with the Example. In the ALD process, a strontium source having a cyclopentadienyl (Cp) ligand and a ruthenium source having a beta diketonate ligand were used.

II indicates a ruthenium content in a strontium ruthenate thin film when oxygen gas was used as an oxidizing agent in the ALD process in accordance with Comparative Example I. III indicates a ruthenium content in a strontium ruthenate thin film when ozone gas was used as an oxidizing agent in the ALD process in accordance with Comparative Example II. IV indicates a ruthenium content in a strontium ruthenate thin film when water vapor and oxygen gas were sequentially used as an oxidizing agent in the ALD process in accordance with Comparative Example III. V indicates a ruthenium content in a strontium ruthenate thin film when oxygen gas and water vapor were used as an oxidizing agent in the ALD process in accordance with Comparative Example IV.

Referring to FIG. 8, when water vapor was used as the oxidizing agent, the strontium ruthenate thin film had more than about 25% ruthenium content while oxygen gas and/or ozone gas were used as the oxidizing agent, the strontium ruthenate thin film had less than about 10% ruthenium content. Thus, when water vapor is used as an oxidizing agent in an ALD process for forming a strontium ruthenate thin film having a cyclopentadienyl (Cp) ligand and a beta diketonate ligand, the strontium ruthenate thin film may have good characteristics.

Evaluation of Step Coverage Characteristics of a Strontium Ruthenium Thin Film

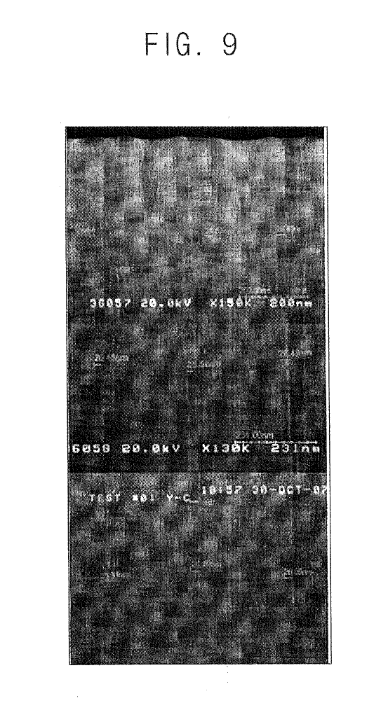

FIG. 9 is a graph illustrating step coverage characteristics of a strontium ruthenate thin film when the strontium ruthenate thin film was formed on a cylindrical structure having an aspect ratio of about 13:1 using water vapor as an oxidizing agent in an ALD process. The step coverage is a ratio of a first thickness of a first portion of the strontium ruthenate thin film on a bottom of the cylindrical structure with respect to a second thickness of a second portion of the strontium ruthenate thin film on an upper portion of the cylindrical structure.

Referring to FIG. 9, the strontium ruthenate thin film having a cyclopentadienyl (Cp) ligand and a beta diketonate ligand had a step coverage of more than about 85%. Thus, the method of forming the strontium ruthenate thin film in accordance with example embodiments may be used for forming capacitors.

According to some example embodiments, when a strontium ruthenate thin film is formed, a strontium source including a ligand having good reactivity with water vapor is used so that a reaction site to which a ruthenium source having a beta diketonate ligand may be adsorbed. Thus, water vapor may be used again as an oxidizing agent for the ruthenium source. The strontium ruthenate thin film may have a greater ruthenium content, and thus, a capacitor having the strontium ruthenate thin film serving as a lower electrode may have good characteristics.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a strontium ruthenate thin film using water vapor as an oxidizing agent in an atomic layer deposition (ALD) process, wherein a strontium source and a ruthenium source are used in the ALD process, the strontium source comprising one selected from the group consisting of a cyclopentadienyl (Cp) ligand, an alkoxide ligand, an alkyl ligand, an amide ligand and a halide ligand, and the ruthenium source comprising a beta diketonate ligand.

2. The method of claim 1, wherein the ruthenium source further comprises a tetramethylheptanedionate (TMHD) ligand and/or a methoxytetramethylheptanedionate (METHD) ligand.

3. The method of claim 1, wherein the strontium source comprises one selected from the group consisting of strontium n-propyl cyclopentadienyl, strontium iso-propyl cyclopentadienyl, strontium n-butoxide, strontium diketiminate, strontium dikeminine and strontium chloride.

4. The method of claim 1, wherein forming the strontium ruthenate thin film comprises:
i) performing a first ALD process using water vapor and the strontium source comprising a ligand that can react with water vapor;
ii) performing a second ALD process using water vapor and the ruthenium source comprising the beta diketonate ligand; and
performing i) and ii) at least twice.

5. A method of forming a strontium ruthenate thin film, comprising:
i) providing a strontium source onto a substrate to be chemically adsorbed on the substrate, the strontium source comprising one selected from the group consisting of a cyclopentadienyl (Cp) ligand, an alkoxide ligand, an alkyl ligand, an amide ligand and a halide ligand;
ii) removing at least a remaining portion of the strontium source that is not chemically adsorbed on the substrate by a first purge process;
iii) providing water vapor onto the substrate to form a strontium oxide thin film on the substrate, the strontium source being reacted with the water vapor;
iv) providing a ruthenium source onto the strontium oxide thin film to be chemically adsorbed on the strontium oxide thin film, the ruthenium source comprising a beta diketonate ligand;
v) removing at least a remaining portion of the ruthenium source that is not chemically adsorbed on the strontium oxide thin film by a second purge process; and
vi) providing water vapor onto the strontium oxide thin film to form a ruthenium oxide thin film, the ruthenium source being reacted with the water vapor.

6. The method of claim 5, further comprising performing a third purge process after forming the strontium oxide thin film and performing a fourth purge process after forming the ruthenium oxide thin film.

7. The method of claim 5, wherein at least one of i) through vi) are performed at least twice.

8. The method of claim 5, wherein the ruthenium source further comprises a tetramethylheptanedionate (TMHD) ligand and/or a methoxytetramethylheptanedionate (METHD) ligand.

9. The method of claim 5, wherein the strontium source comprises one selected from the group consisting of strontium n-propyl cyclopentadienyl, strontium iso-propyl cyclopentadienyl, strontium n-butoxide, strontium diketiminate, strontium dikeminine and strontium chloride.

10. A method of manufacturing a capacitor, comprising:
forming a lower electrode using a strontium ruthenate thin film;
forming a dielectric layer on the lower electrode; and
forming an upper electrode on the dielectric layer,
wherein the strontium ruthenate thin film is formed using water vapor, a strontium source and a ruthenium source by an ALD process, the strontium source comprising one selected from the group consisting of a cyclopentadienyl (Cp) ligand, an alkoxide ligand, an alkyl ligand, an amide ligand and a halide ligand, and the ruthenium source comprising a beta diketonate ligand.

11. The method of claim 10, wherein the ruthenium source further comprises a tetramethylheptanedionate (TMHD) ligand and/or a methoxytetramethylheptanedionate (METHD) ligand.

12. The method of claim 10, wherein the strontium source comprises one selected from the group consisting of strontium n-propyl cyclopentadienyl, strontium iso-propyl cyclopentadienyl, strontium n-butoxide, strontium diketiminate, strontium dikeminine and strontium chloride.

13. The method of claim 10, wherein forming the strontium ruthenate thin film comprises:
i) performing a first ALD process using water vapor and the strontium source comprising a ligand that can react with water vapor;
ii) performing a second ALD process using water vapor and the ruthenium source comprising the beta diketonate ligand; and
performing i) and ii) at least twice.

14. The method of claim 10, wherein forming the strontium ruthenate thin film comprises:
i) providing the strontium source onto a substrate to be chemically adsorbed on the substrate, the strontium source comprising one selected from the group consisting of a cyclopentadienyl (Cp) ligand, an alkoxide ligand, an alkyl ligand, an amide ligand and a halide ligand;
ii) removing at least a remaining portion of the strontium source that is not chemically adsorbed on the substrate by a first purge process;
iii) providing water vapor onto the substrate to form a strontium oxide thin film on the substrate, the strontium source being reacted with the water vapor;
iv) providing the ruthenium source onto the strontium oxide thin film to be chemically adsorbed on the strontium oxide thin film, the ruthenium source comprising a beta diketonate ligand;
v) removing at least a remaining portion of the ruthenium source that is not chemically adsorbed on the strontium oxide thin film by a second purge process; and
vi) providing water vapor onto the strontium oxide thin film to form the ruthenium oxide thin film, the ruthenium source being reacted with the water vapor.

15. The method of claim 14, further comprising performing a third purge process after forming the strontium oxide thin film and performing a fourth purge process after forming the ruthenium oxide thin film.

16. The method of claim 14, wherein at least one of i) through vi) are performed at least twice.
